(19) United States
(12) Patent Application Publication
(10) Pub. No.: US 2026/0312600 A1
(43) Pub. Date: Oct. 8, 2026

(54) DELTA-SIGMA SENSING DEVICE

(71) Applicants: Universitat Autónoma de Barcelona, Bellaterra, Barcelona (ES); Consejo Superior de Investigaciones Científicas (CSIC), Madrid (ES)

(72) Inventors: Josep Maria Margarit Taulé, Bellaterra, Barcelona (ES); Javier Cuenca Michans, Bellaterra, Barcelona (ES); Lluís Terés Terés, Bellaterra, Barcelona (ES); Francisco Serra Graells, Bellaterra, Barcelona (ES)

(21) Appl. No.: 19/485,424

(22) PCT Filed: May 20, 2024
(86) PCT No.: PCT/EP2024/063866

§ 371 Date: Nov. 18, 2025

(30) Foreign Application Priority Data
May 19, 2023 (EP) 23382470.5

(51) Int. Cl. H03M 3/00

(52) U.S. Cl. CPC H03M 3/356; H03M 3/344; H03M 3/504

(57) ABSTRACT

Delta-sigma device comprising transducers (2) and delta-sigma modulators (3) wherein the transducers (2) comprise: a sensing stage (100) that detect a property of the environment (106) and an interfacing stage (101); and the delta-sigma modulators (3) comprise: an input stage connected to the interfacing stages (101), comprising the input stage two subtracting stages (113, 114), for receiving an unfiltered intramodulator feedback signal (109) and a low-pass-filtered intramodulator feedback signal (110), and subtracting them from a sum of one or more of the input transduced signals (108) to obtain a delta error signal (111), a feedforward low-pass filtering stage (102); an analog-to-digital encoder (104), that converts the filtered delta error signal into a digital output signal dₒᵤₜ(t) (112), an unfiltered intramodulator feedback path, that converts dₒᵤₜ(t) (112) into the unfiltered intramodulator feedback signal (109), and a low-pass-filtered intramodulator feedback path, that converts dₒᵤₜ(t) (112) into the low-pass-filtered intramodulator feedback signal (110).

### OBJECT OF THE INVENTION

The object of the present invention is a delta-sigma sensing device with background signal attenuation and distributed encoding.

### BACKGROUND OF THE INVENTION

Sensor technologies play a critical role in various industries, including environmental monitoring, automotive, aerospace, medical, and consumer electronics. These sensors are designed to measure and monitor different physical (e.g., pressure, temperature, humidity) and chemical (e.g., analyte concentrations) parameters, providing essential data for a wide range of applications. To enable the sensors to communicate with other devices for performing further computation, the sensors are commonly “smartened” by incorporation of integrated circuits for processing the sensor signal and converting it into a digital format readable from external user devices.

Achieving high precision and accuracy in smart sensing devices is often hampered by factors such as drift and offset. Drift refers to a slow, continuous change in the output of a sensor over time, independent of the input signal of interest. This can be attributed to aging, contamination of the sensing surface, and other environmental factors such as thermal, mechanical or electrical stress. Offset, on the other hand, is a constant component in the sensor output signal, regardless of the input value. It is usually caused by manufacturing imperfections or other external influences. Inaccurate measurements may lead to incorrect decision-making, reduced system efficiency, and, in some cases, critical failures.

In practice, calibration of these two factors is frequently required for the sensing devices to perform within operational requirements. Calibration needs represent a key challenge to device autonomy together with energy consumption. A third aspect miniaturization-adds to autonomy as crucial trait for enabling a ubiquitous usage of the devices. Recent advances to sensor technologies enable fabrication of physical and chemical sensors below the microscale. But, as the amplitude of the signals transduced decreases with size, downscaling accentuates the sensitivity to the aforementioned drift and offset effects.

Different strategies have been described in the state of the art to compensate for drift: A common one, subtracting a cancellation term from the sensor output during a calibration phase, is not effective for monitoring along extended periods of time as drift varies due to environmental determinants. Other popular techniques, like using a threshold to differentiate between signal changes and drift rely on the signal being larger than drift, which may not always be the case. Performing a differential measurement from a reference sensor requires electrical matching and drift similarity between the two, which might not be feasible due to intrinsic manufacturing variability. Circuit methods proposed for removing or cancelling offset involve applying a bias at the device, reconfigured within a limited range during a separate calibration phase. The adoption of machine learning algorithms and artificial intelligence (AI) in sensor systems can also help to detect and compensate drift and offset. By analyzing historical sensor data and identifying patterns, these algorithms can predict and correct the resulting errors in real-time, leading to more accurate and reliable measurements. However, and due to their complexity, embedding AI models in a device generally translates into a substantial increase in its dimensions and energy budget.

In this scenario, electrochemical microsensors fabricated in semiconductor technologies offer advantages such as miniaturization, mass fabrication, and ease of integration with CMOS circuits for embedding signal processing as smart sensing devices.

Indeed, the amperometric sensor family shown in FIG. 1 is particularly appealing since a simple three-microelectrode cell structure allows to evaluate redox reactions in solution at a target analyte potential (VRW) between reference (RE) and working (WE) electrodes. Under potentiostatic operation, that is ensuring a constant voltage at VRW and also null current through RE, the counter electrode (CE) supplies all the current needed for the electrochemical reaction at the surface of the WE. Thus, unwanted voltage drops of VRW at RE can be effectively avoided.

In this configuration, the electrode-electrolyte interface is usually modelled as the small-signal electrical circuit of FIG. 1, where iₛₑₙₛ is the CE-WE current change to be measured, while R_{ct}, C_{dl} and Rₛ stand for the charge transfer resistance, the double layer capacitance and the electrolyte solution resistance, respectively.

FIG. 2 shows a field-effect transistor (FET) sensor easy to miniaturize and replicate as sensor array in semiconductor technologies. In standard CMOS technologies, the FET can be integrated as a metal-oxide-semiconductor transistor with the metal connection at the gate replaced by a liquid. The liquid contains the target analytes to be measured, which interact with the gate insulator functionalized as sensing surface. Changes in the analyte concentrations are transduced into a potential change at the gate insulator surface dependent upon the sensitivity to each analyte. These electrical variations in the gate potential can then be read out in the electrical domain by use of electronic circuits.

In the case of a FET electrochemical sensor fabricated in a standard CMOS technology, the FET can be modelled as the electrical circuit of FIG. 2, where Vₛₑₙₛ is the potential change to be measured due to a variation in the chemical contribuent V_{chem}, while Cₛₑₙₛ stand for the sensing capacitance due to the dielectric sensing membrane.

Despite the aforementioned advantages, the practical usage of electrochemical microsensors is limited by phenomena like fouling and parasitic currents or trapped charges at the sensing surface (e.g., drifting and offset components). Such phenomena introduce variability between sensors and can severely impair the dynamic range and accuracy of transient measurements.

Drift is particularly problematic for small signals and long-term measurements as it can be difficult to identify the signal amongst the shifting baseline. Together with offset components-and in the context of sensor readout, the sensor output can be driven outside of the analogue-to-digital converter input range and saturate. This also means an analogue-to-digital converter will need to cover a wide input range, which can increase quantization noise.

Classic solutions to integrate the potentiostatic-amperometric readout in CMOS technologies employ potentiostat circuits based on operational amplifiers that enforce a negative feedback loop of the CE current in order to control VRW. The resulting sensor current can then be translated into voltage and converted to the digital domain through pulse-width or pulse-density modulators.

Recent efforts have been directed to fusing both, the potentiostat and ADC functions, into a single circuit block using delta-sigma modulators. An interesting concept related with this scenario is what is known as sensor in the loop: reusing the sensor dynamics available shown in FIG. 1 as feedforward filtering stage for quantization noise shaping inside a delta-sigma modulator with either discrete- or continuous-time feedback. Apart from the obvious advantage of circuit power and area savings, the reuse of the sensor as continuous-time feedforward filter automatically adapts its anti-aliasing cut-off frequency to the sensor intrinsic bandwidth.

In the case of field-effect-transistor (FET) sensors, the common approach is to use the transistor as a voltage follower. More recent circuits read out the device in current mode, which facilitates direct filtering and the use of delta-sigma modulation schemes alike to the ones previously described for amperometric sensors.

On-and off-chip compensation methods have been proposed to overcome sensor offsets and drifts to some extent. However, none of the former approaches addresses, for instance, how to monitor in the long term under drift or offset interferents, which can have higher intensity than the signals of interest and may be influenced by evolving environmental factors. This is the case of commercial applications like environmental monitoring or wearable chemical sensing, in which the wide adoption of these analytical systems is still limited mainly due to sensor non-idealities, and due to the restricted deployability of these devices in terms of compactness and energy autonomy.

### DESCRIPTION OF THE INVENTION

The delta-sigma sensing device of the present invention has built-in adaptive pulse modulation encoding for delivering sensor biasing, analog-to-digital conversion, and attenuation of undesired background sensor signals (e.g., DC offset, drifts) lying out of the frequency band of interest.

The device comprises one or more transducers and one or more delta-sigma modulators. Firstly, each of the transducers comprises a sensing stage intended to detect a property of the environment such as temperature, humidity, analyte concentrations, and to convert it into an electrical input signal. Each transducer also comprises an interfacing stage, connected to the sensing stage, that receives the electrical input signal, amplifies the electrical input signal to facilitate further processing, and outputs amplified input transduced signals to one or more of the delta-sigma modulators.

Secondly, each of the delta-sigma modulators comprises an input stage, connected to the interfacing stage, configured to receive an unfiltered intramodulator feedback signal and a low-pass-filtered intramodulator feedback signal, and to subtract them from a sum of one or more of the amplified input transduced signals to obtain a delta error signal.

Following the input stage, each modulator comprises a feedforward low-pass filtering stage, that filters the delta error signal, generating a filtered delta error signal, and an analog-to-digital encoder, following the feedforward low-pass filtering stage, that converts the filtered delta error signal into a digital output signal dₒᵤₜ(t).

Between the analog-to-digital encoder and the input stage, the modulator comprises an unfiltered intramodulator feedback path, that converts dₒᵤₜ(t) into the unfiltered intramodulator feedback signal, and a low-pass-filtered intramodulator feedback path, between the analog-to-digital encoder and the input stage, that converts dₒᵤₜ(t) into the low-pass-filtered intramodulator feedback signal.

In front of the state of the art, the present invention offers:
(i) tunable compression of interfering frequency components to increase the dynamic range, the readout resolution, and the energy efficiency; and
(ii) distributed pulse modulation encoding, to increase the maximum overall encoder sampling rate and to effectively model dependencies between the input signals transduced by the sensors.

The delta-sigma device of the invention is characterized in that it comprises one or more transducers and one or more delta-sigma modulators wherein each of the transducers comprises:
a sensing stage intended to detect a property of the environment Xᵢₙ(t) and configured to convert it into an electrical input signal, and
an interfacing stage, connected to the sensing stage, and configured to receive the electrical input signal, amplify the electrical input signal and send amplified input transduced signals to one or more of the delta-sigma modulators,
   and wherein each of the delta-sigma modulators comprises:
an input stage connected to the interfacing stages, comprising two subtracting stages, and configured to receive an unfiltered intramodulator feedback signal and a low-pass-filtered intramodulator feedback signal, and to subtract them from a sum of one or more of the amplified input transduced signals to obtain a delta error signal,
a feedforward low-pass filtering stage, following the two subtracting stages of the input stage, configured to filter the delta error signal, generating a filtered delta error signal;
an analog-to-digital encoder, following the feedforward low-pass filtering stage, that converts the filtered delta error signal into a digital output signal dₒᵤₜ(t),
an unfiltered intramodulator feedback path, that comprises one or more first digital-to-analog converters between the analog-to-digital encoder and a first of the two subtracting stages of the input stage, that converts dₒᵤₜ(t) into the unfiltered intramodulator feedback signal, and
a low-pass-filtered intramodulator feedback path that comprises a feedback low-pass filtering stage and one or more second digital-to-analog converters, between the analog-to-digital encoder and a second of the two subtracting stages of the input stage, that converts dₒᵤₜ(t) into the low-pass-filtered intramodulator feedback signal;
and wherein the cut-off frequency of the feedback low-pass filtering stage is set between the range of background signal components and the range of signal of interest components.

Thus, the feedback low-pass filtering stage is configured to let the background signal components to pass and to supress the signal of interest. Since the feedback low-pass filtering stage is subtracted from the amplified input transduced signals it functions as a high-pass filter subtracting the low-frequency background signals.

Preferably, the cut-off frequency of the feedback low-pass filtering stage is set to be higher than the background signal components and lower than the signal of interest components.

In some embodiments, it is not possible to select a cut-off frequency that lets the background signal components to pass and that supress all the signal of interest. Thus, the background signal components cannot be completely filtered. In those cases, a trade-off solution is adopted wherein the cut-off frequency selected blocks part of the background signal components and/or let par of the signal of interest components to pass.

Preferably, the background signals are a drift and/or an offset.

Each transducer could be connected to a single delta-sigma modulator or to more than one delta-sigma modulator.

The device of the invention can also comprise one or more transducers and two or more delta-sigma modulators, and wherein the device additionally comprises a plurality of unfiltered intermodulator feedback paths that comprise one or more third digital-to-analog converters, connected to dₒᵤₜ(t) of each delta-sigma modulator and configured to convert dₒᵤₜ(t) into a plurality of unfiltered intermodulator feedback signals, and wherein the device comprises an additional subtracting stage before the feedforward low-pass filtering stage configured to receive the unfiltered intermodulator feedback signals of each one of the other delta-sigma modulators to subtract them from the delta error signal.

Preferably, the feedforward low-pass filtering stage and/or the feedback low-pass filtering stage comprise one or more leaky or non-leaky integrator stages, each integrator stage being configured to integrate a respective input signal.

Preferably, the one or more of the leaky or non-leaky integrator stages of the feedforward low-pass filtering stage are a small-signal circuit equivalent of the dynamic electrical response of the transducer under small-signal excitation.

Also, the analog-to-digital encoder of the delta-sigma modulators could comprise a one-bit synchronous or asynchronous quantizer or a three-level asynchronous or synchronous quantizer.

More preferably, the analog-to-digital encoder of the delta-sigma modulators could comprise a one-bit asynchronous quantizer and a pulse generator that convert the filtered delta error signal into a digital pulsing signal dₒᵤₜ(t).

The feedback low-pass filtering stage could additionally comprise a FIR (Finite Impulse Response) or IIR (Infinite Impulse Response) digital low-pass filter.

Preferably, the feedback low-pass filtering stage could additionally comprise an asynchronous counter stage, with a predetermined clock period, connected between dₒᵤₜ(t) and the digital low-pass filter, and configured to integrate the number of asynchorous dₒᵤₜ(t) pulses throughout such predetermined clock period.

The analog-to-digital encoders of the delta-sigma modulators could comprise a three-level asynchronous quantizer and a three-level bipolar pulse generator that convert the filtered delta error signal into a digital bipolar pulsing signal dₒᵤₜ(t), wherein the three-level asynchronous quantizer is configured to send a signal to the three-level bipolar pulse generator to generate three different digital signals each one corresponding to a predetermined range of values of the filtered delta error signal received.

Preferably, the sensing stage and the interfacing stage of the transducers and a leaky integrator stage of the feedforward low-pass filtering stage are three-electrode cells operating as a potentiostatic-amperometric sensor, and wherein the unfiltered intramodulator feedback signals and the low-pass-filtered intramodulator feedback signals are subtracted in current-mode from the amplified input signals, and the unfiltered intermodulator feedback signals are subtracted in current-mode from the inputs of any of the integrator stages comprised in the feedforward low-pass filtering stage, wherein the feedforward low-pass filtering stage is connected to the unfiltered intramodulator feedback path and the low-pass filtered intramodulator feedback path.

The device of the invention could further comprise a second current source in the unfiltered intramodulator feedback path configured to perform digital-to-analog conversion controlled by dₒᵤₜ(t), and a first current source comprised of a metal-oxide-semiconductor (MOS) transistor configured to perform amplification and digital-to-analog conversion of the low-pass intramodulator feedback path controlled by dₒᵤₜ(t).

Preferably, the metal-oxide-semiconductor (MOS) transistor could be operated with a selectable drain-source voltage biased to have a null drain-source voltage when the output of dₒᵤₜ(t) is zero or to a null source-bulk voltages, and, when the output of dₒᵤₜ(t) is not zero, a non-zero very low drain-source voltage is selected, being proportional to dₒᵤₜ(t).

In preferred embodiments, the sensing stage could comprise a FET sensor, and the interfacing stage performs capacitive amplification through the passivation capacitance of the FET sensor and a feedback capacitance, and wherein the unfiltered intramodulator feedback signals, the low-pass-filtered intramodulator feedback signals, and the unfiltered intermodulator feedback signals are subtracted in current-mode from the amplified input transduced signals.

### DESCRIPTION OF THE DRAWINGS

To complement the description of the invention for a better understanding of its characteristics, and in accordance with a preferred example of practical embodiment thereof, a set of drawings is attached as an integral part of said description. The drawings represent, with illustrative and non-limiting character:

FIG. 1.—Shows the small-signal electrical model of the electrode-electrolyte interfaces for a three-electrode electrochemical cell of the state of the art.

FIG. 2.—Shows the electrical model of a FET electrochemical sensor of the state of the art fabricated in a standard CMOS technology.

FIG. 3.—Shows a general schematic representation of a first example implementation of the device, in which each transducer is connected to a unique delta-sigma modulator.

FIG. 4.—Show a detailed schematic representation of a first example implementation of the device, in which each transducer is connected to a unique delta-sigma modulator.

FIG. 5.—Shows a general schematic representation of a second example implementation of the device, in which one or more transducers are connected to one or more delta-sigma modulators.

FIG. 6.—Shows a detailed schematic representation of a second example implementation of the device, in which one or more transducers are connected to one or more delta-sigma modulators.

FIG. 7.—Shows a general schematic representation of a third example implementation of the device, in which some of the transducers are connected to more than one delta-sigma modulator, and wherein some of the outputs of the delta-sigma modulators are fed back to some of the other delta-sigma modulators that comprise the device.

FIG. 8.—Shows a detailed schematic representation of a third example implementation of the device, in which some of the transducers are connected to more than one delta-sigma modulator, and wherein some of the outputs of the delta-sigma modulators are fed back to some of the other delta-sigma modulators that comprise the device.

FIGS. 9A and 9B.—Show a detailed schematic representation of the device implemented according to a first embodiment, in which a FET electrochemical transducer is connected to a delta-sigma modulator.

FIG. 10.—Shows a detailed schematic representation of the device implemented according to a second embodiment, in which one or more FET electrochemical transducers are connected to one or more delta-sigma modulators.

FIG. 11.—Shows a detailed schematic representation of the device implemented according to a third embodiment, in which a three-electrode cell-operating as a potentiostatic-amperometric transducer-is connected to a delta-sigma modulator.

FIG. 12.—Shows a detailed schematic representation of the device implemented according to a fourth embodiment, in which one or more three-electrode cells, operating as a potentiostatic-amperometric transducers, are connected to one or more delta-sigma modulators.

FIG. 13.—Shows the signal recovered after demodulating the transient response (bottom) of the first embodiment of the device to a prototypical increase in the analyte concentration causing a transition in the effective rate of Vₛₑₙₛ under constant, and substantial, drift rate (top).

FIG. 14.—Shows the signal recovered after demodulating the transient response (bottom) of the third embodiment of the device to an Iₛₑₙₛ in line with a prototypical half voltammetry cycle with large resistive losses at the working electrode-electrolyte interface (top).

### PREFERRED EMBODIMENT OF THE INVENTION

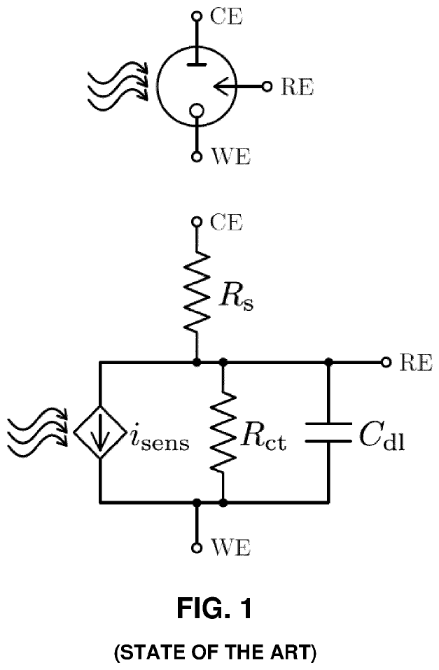

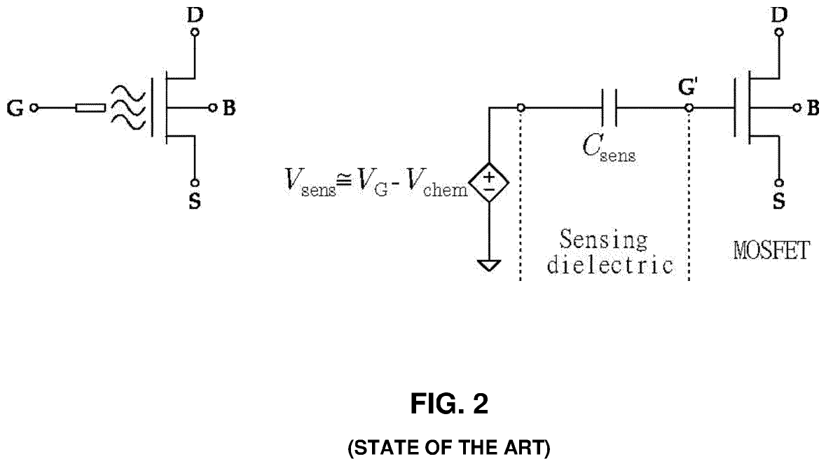

It is described below, with the help of FIGS. 1 to 14, a preferred embodiment of the delta-sigma device with background signal attenuation and distributed encoding, object of the present invention. It is to be noted that the use of words “first” and “second” may not imply any kind of particular order or hierarchy unless such order or hierarchy is explicitly or implicitly made clear in the context.

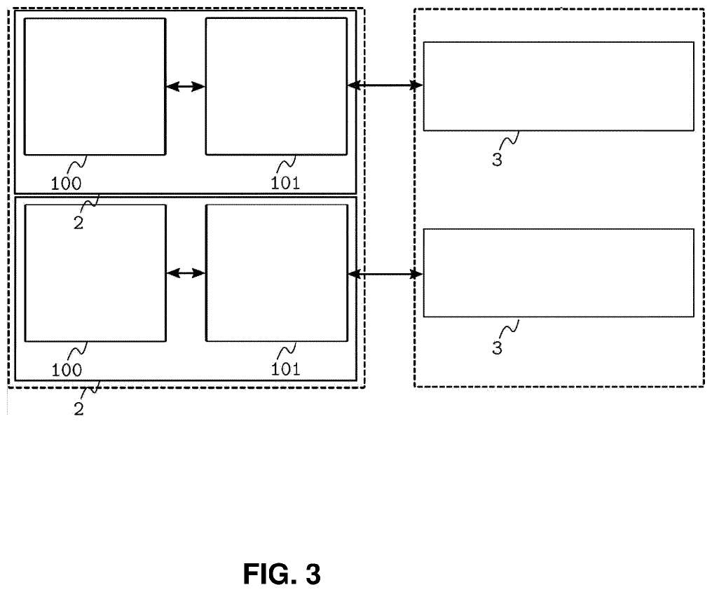

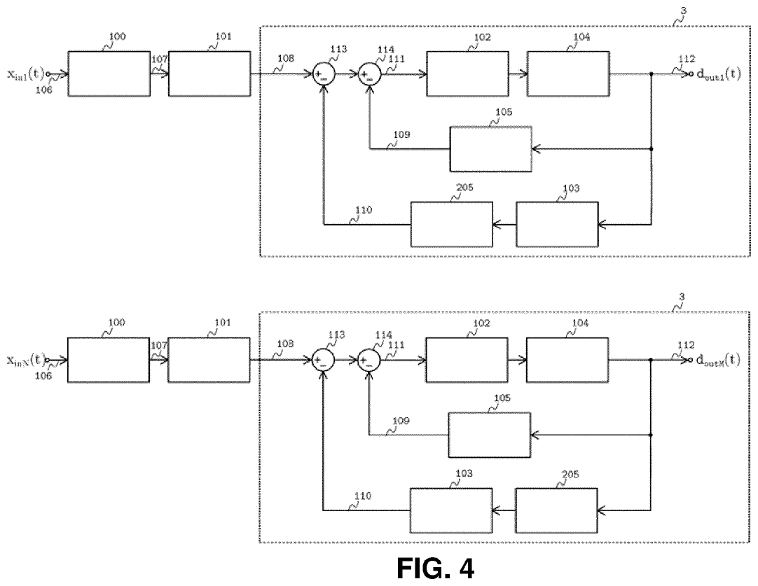

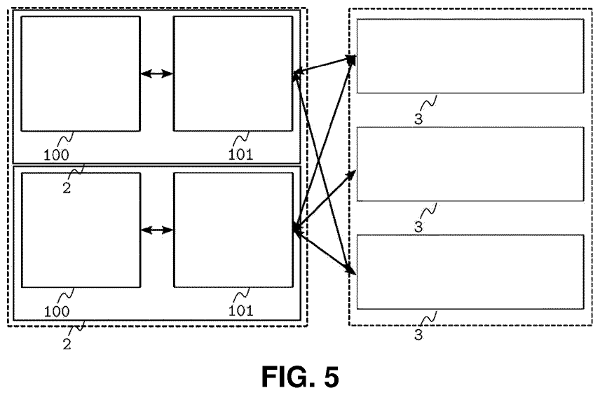

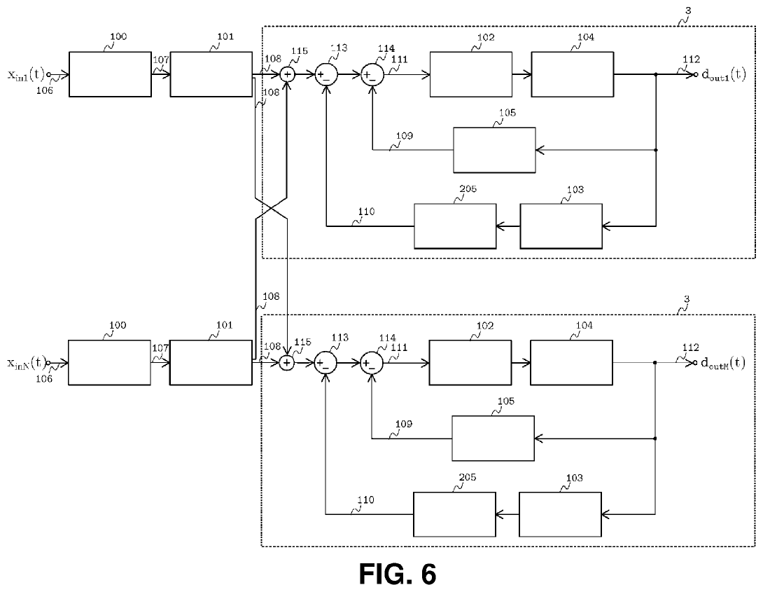

As presented in FIGS. 3 and 5, the delta-sigma device comprises one or more transducers (2) and one or more delta-sigma modulators (3). As shown in detail in FIGS. 4 and 6, each of the transducers (2) comprises a sensing stage (100) intended to detect a property of the environment Xᵢₙₜ(t) (106) and configured to convert it into an electrical input signal (107), and an interfacing stage (101), connected to the sensing stage (100), that receives the electrical input signal (107), amplifies the electrical input signal (107) to facilitate further processing, and outputs amplified input transduced signals (108) to one (FIG. 4) or more (FIG. 6) of the delta-sigma modulators (3).

Moreover, each of the delta-sigma modulators (3) comprises, as shown in FIGS. 4 and 6, an input stage connected to the interfacing stages (101), comprising the input stage two subtracting stages (113, 114). The subtracting stages (113, 114) configured to receive an unfiltered intramodulator feedback signal (109) and a low-pass-filtered intramodulator feedback signal (110), and to subtract them from a sum of one (FIG. 4) or more (FIG. 6) amplified input transduced signals (108) to obtain a delta error signal (111).

Following both subtracting stages (113, 114) of the input stage, each modulator (3) comprises a feedforward low-pass filtering stage (102), configured to filter the delta error signal, generating a filtered delta error signal, an analog-to-digital encoder (104), following the feedforward low-pass filtering stage (102), that converts the filtered delta error signal into a digital output signal dₒᵤₜ(t) (112), an unfiltered intramodulator feedback path, between the analog-to-digital encoder (104) and the two subtracting stages (113, 114) of the input stage, that converts dₒᵤₜ(t) (112) into the unfiltered intramodulator feedback signal (109), and a low-pass-filtered intramodulator feedback path, between the analog-to-digital encoder (104) and the two subtracting stages (113, 114) of the input stage, that converts dₒᵤₜ(t) (112) into the low-pass-filtered intramodulator feedback signal (110). The low-pass-filtered intramodulator feedback path enables compression of background signals of low-pass frequency to increase the dynamic range, the readout resolution, and the energy efficiency of the delta-sigma device.

In an aspect of the invention, shown in FIGS. 3 and 4, each transducer (2) is connected to a unique delta-sigma modulator (3).

In an aspect of the invention, presented in FIGS. 5 and 6, each transducer (2) is connected to more than one delta-sigma modulators (3). In particular, the output of the interfacing stage (101) of a first delta-sigma modulator (3) is connected to an intermodulator subtracting stage (115), that the input stage also comprises before the two subtracting stages (113, 114), of a second delta-sigma modulator (3).

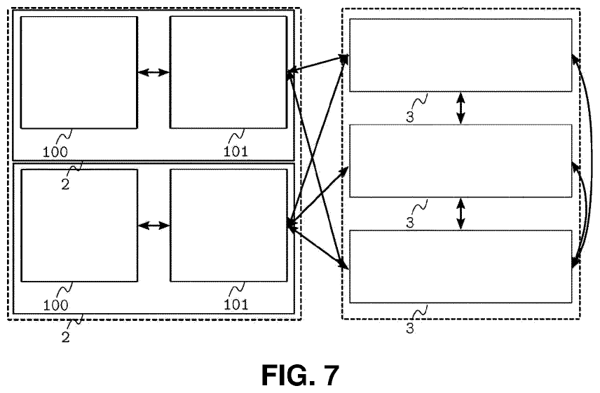

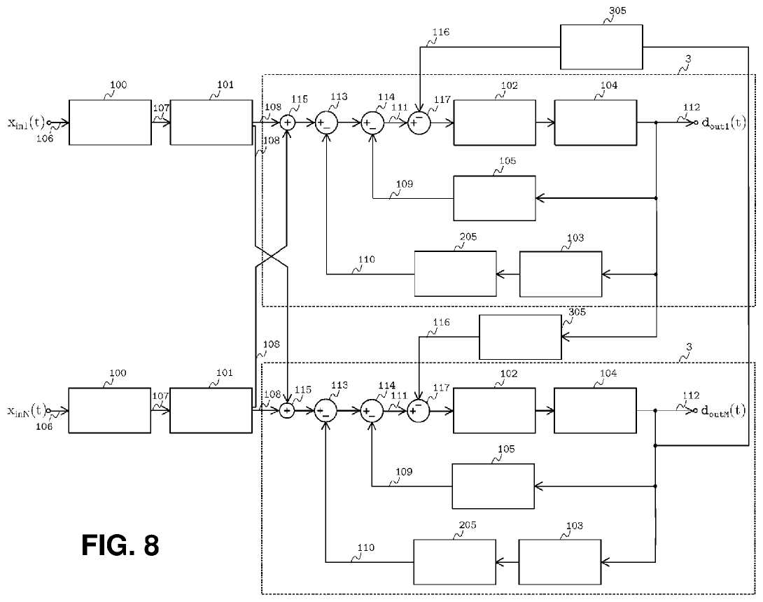

In an aspect of the invention, disclosed in FIGS. 7 and 8, the device comprises one or more transducers (2) and two or more delta-sigma modulators (3). In this case, the device additionally comprises a plurality of unfiltered intermodulator feedback paths, connected to dₒᵤₜ(t) (112) of each delta-sigma modulator (3) and configured to convert dₒᵤₜ(t) into a plurality of unfiltered intermodulator feedback signals (116). What is more, the device comprises an additional subtracting stage (117) before the feedforward low-pass filtering stage (102) that is configured to receive the unfiltered intermodulator feedback signals (116) of each one of the other delta-sigma modulators (3) to subtract them from the delta error signal (111). Adding the the intermodulator feedback paths allows to distribute pulse modulation encoding among the delta-sigma modulators. This is an important feature to increase the maximum overall encoder sampling rate and to effectively model dependencies between the input signals transduced by the sensors.

In an aspect of the invention, the unfiltered intramodulator feedback paths comprise one or more first digital-to-analog converters (105) and/or the unfiltered intermodulator feedback paths comprise one or more third digital-to-analog converters (305).

In an aspect of the invention the low-pass-filtered intramodulator feedback paths comprise a feedback low-pass filtering stage (103) and a one or more second digital-to-analog converters (205).

The second digital-to-analog-converters (205) can be placed before or after the low-pass filter, as shown in FIG. 4.

In an aspect of the invention, the feedforward low-pass filtering stage (102) and the feedback low-pass filtering stage (103) comprise one or more leaky or non-leaky integrator stages, each integrator stage being configured to integrate a respective input signal.

Regarding this embodiment, the low-pass filtering stage can be implemented combining multiple feedback and feedforward loops in a backbone made of integrator stages cascaded in series. Negative feedback is used to connect integrator outputs to the inputs of same or previous integrator stages in order to regulate the gain and frequency response of the filter. Feedforward connects the output of each integrator stage to the input of next stages in order to compensate for phase and amplitude distortion introduced by the feedback mechanism.

What is more, a leaky integrator is a stage that receives an input signal and generates an output signal by integrating a leaked signal over time. The leaked signal is obtained based on a dampening factor applied to reduce the amplitude of the input signal. A non-leaky integrator is a stage that receives an input signal and generates an output signal by integrating the input signal without any leakage or dampening.

In an aspect of the invention, one or more of the leaky or non-leaky integrator stages of the feedforward low-pass filtering stage (102) comprises a small-signal circuit equivalent of the dynamic electrical response of the transducer (2).

A small-signal circuit equivalent is a simplified representation of the dynamic response of a device that describes its electrical behavior under small-signal excitation. The small-signal circuit equivalent consists of a set of linear circuit elements, such as resistors, capacitors, and controlled sources, that are connected to model the device.

In an aspect of the invention, the analog-to-digital encoder (104) of the delta-sigma modulators (3) comprises a one-bit synchronous or asynchronous quantizer.

In an aspect of the invention, the analog-to-digital encoder (104) of the delta-sigma modulators (3) comprises a one-bit asynchronous quantizer connected to a pulse generator that convert the filtered delta error signal into a digital pulsing signal dₒᵤₜ(t) (112). The one-bit asynchronous quantizer is configured to send a signal to the pulse generator to generate a digital signal when the filtered delta error signal received is above a predetermined threshold signal.

In an aspect of the invention, the analog-to-digital encoders (104) of the delta-sigma modulators (3) comprise a three-level asynchronous quantizer and a three-level bipolar pulse generator that convert the filtered delta error signal into a digital, bipolar pulsing signal dₒᵤₜ(t) (112). The three-level asynchronous quantizer is configured to send a signal to the three-level bipolar pulse generator to generate three different digital signals each one corresponding to a predetermined range of values of the filtered delta error signal received.

Regarding the previously described embodiments, a one-bit asynchronous quantizer is a stage that converts a continuous or discrete signal into a “0” or “1” binary signal using a thresholding operation. A one-bit synchronous quantizer converts a continuous or discrete signal into a binary signal using a thresholding operation and a sampling clock. It maps the input signal to either “0” or “1” at regular intervals determined by the clock frequency. A three-level asynchronous quantizer converts a continuous or discrete signal into three output levels using a thresholding operation. A three-level synchronous quantizer converts a continuous or discrete signal into three output levels using a thresholding operation and a clock determining regular sampling intervals.

Furthermore, a digital pulsing signal consists of a sequence of square wave electrical pulses, each occupying one of two discrete, binary levels of amplitude: “0” or “1”. A bipolar pulsing signal consists of a sequence of square wave electrical pulses, each occupying one of three discrete levels of amplitude: positive, negative or zero.

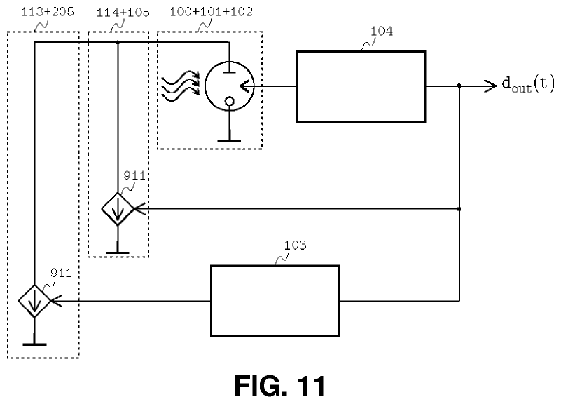

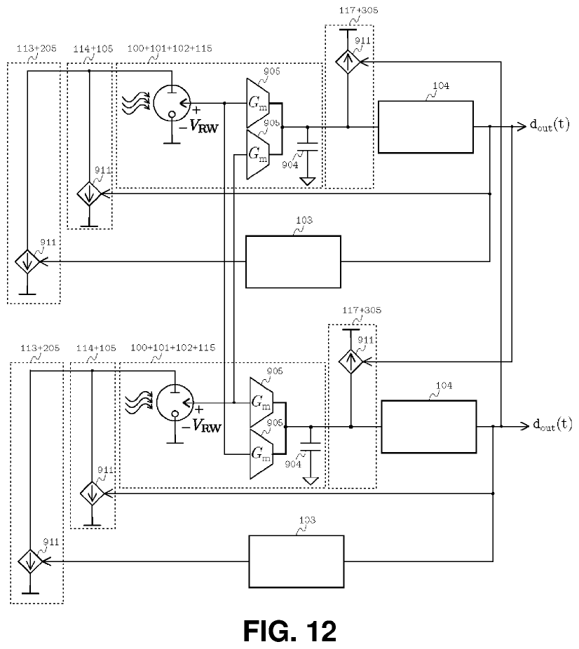

In an aspect of the invention, shown in FIGS. 11 and 12, the sensing stage (100) and the interfacing stage (101) of the transducers (2) and the feedforward low-pass filtering stage (102) are three-electrode cells operating as a potentiostatic-amperometric sensor, wherein the unfiltered intramodulator feedback signals (109) and the low-pass-filtered intramodulator feedback signals (110) are current signals subtracted in current-mode from the amplified input transduced signal (108) of the delta sigma modulators of the device, and the unfiltered intermodulator feedback signals (116) are subtracted in current-mode from the inputs of the second integrator stages comprised in the feedforward low-pass filtering stages. The three-electrode cells are connected to the analog-to-digital encoder (104) which outputs the digital output signal dₒᵤₜ(t) (112). The unfiltered intramodulator feedback path and low-pass filtered intramodulator feedback path are connected after the analog-to-digital encoder (104). Also, the unfiltered intramodulator feedback path and low-pass filtered intramodulator feedback path are connected to the three-electrode cells. The three-electrode cells have a small-signal circuit equivalent.

In all feedback signals of FIG. 11, the digital-to-analog conversion is performed using current sources (911) controlled by dₒᵤₜ(t) or the output of the feedback low-pass filtering stage (103). To allow programmable and miniaturized filtering of very low cut-off frequencies in a microchip, the feedback low-pass filtering stage (103) of the low-pass-filtered intramodulator feedback path is implemented in the digital domain. To this end, an implementation of the feedback low-pass filtering stage (103) can comprise a FIR (Finite Impulse Response) or IIR (Infinite Impulse Response) digital low-pass filter. In the case of asynchronous quantization, an implementation of the feedback low-pass filtering stage (103) can comprise an asynchronous counter stage, with a predetermined clock period, connected between dₒᵤₜ(t) and the digital low-pass filter, and configured to integrate the number of asynchorous dₒᵤₜ(t) pulses throughout the clock period. The sensed currents Iₛₑₙₛ are integrated by the sensor in the loop.

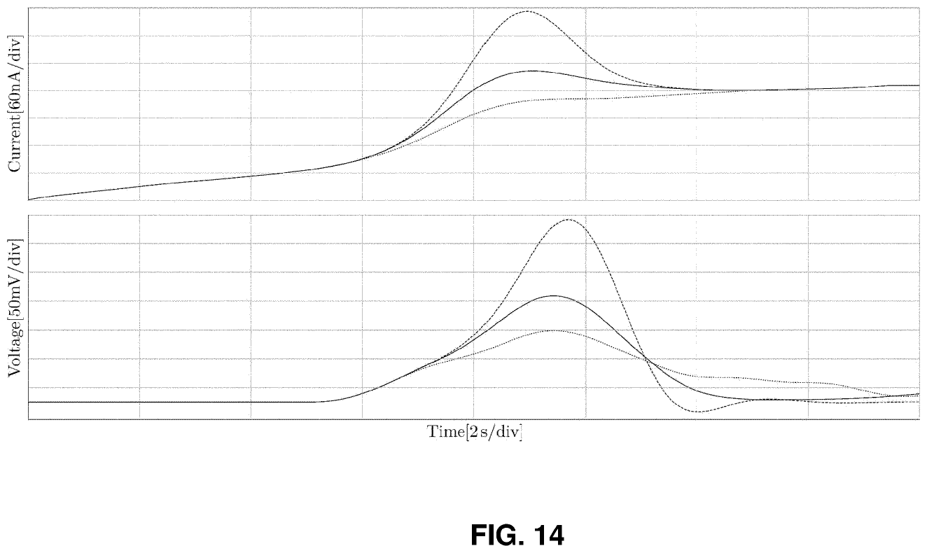

In FIG. 14, dashed, solid, and dotted lines correspond to voltammetries with oxidation peaks of decreasing magnitude, respectively. As seen in FIG. 14 (bottom), the device can be configured to compress the increasing sum of background and effective Iₛₑₙₛsignals into recovered bumps of decreasing magnitude by setting the cut-off frequency of the low-pass-filtered intramodulator feedback path at a value higher than that of the background signals for which attenuation is desired, and lower than the spectral components of interest of the effective Iₛₑₙₛ signal. This facilitates discrimination of both the analyte concentration and electrode kinetics. It also extends the dynamic range available over time to read out the information of interest.

In FIG. 12, the multiple Iₛₑₙₛ generated by the multiple transducers are integrated by each sensor in the loop, and the resulting integrated voltage signals are converted again to current by the transconductors (905) and summed up together in this current domain. The resulting summed current signal is integrated in the integrating capacitor (904) of a second integrator stage. Thus, the multiple Iₛₑₙₛ generated are transmitted to the different delta-sigma modulators (3), before the transconductors (905). Also, unfiltered intermodulator feedback paths are defined in FIG. 12, connecting the output of the analog-to-digital encoder (104) of a first delta-sigma modulator (3) to each one of the other delta-sigma modulators (3) before its analog-to-digital encoder (104). The digital-to-analog conversion of the unfiltered intermodulator feedback signals (116) is performed using current sources (911) controlled by dₒᵤₜ(t).

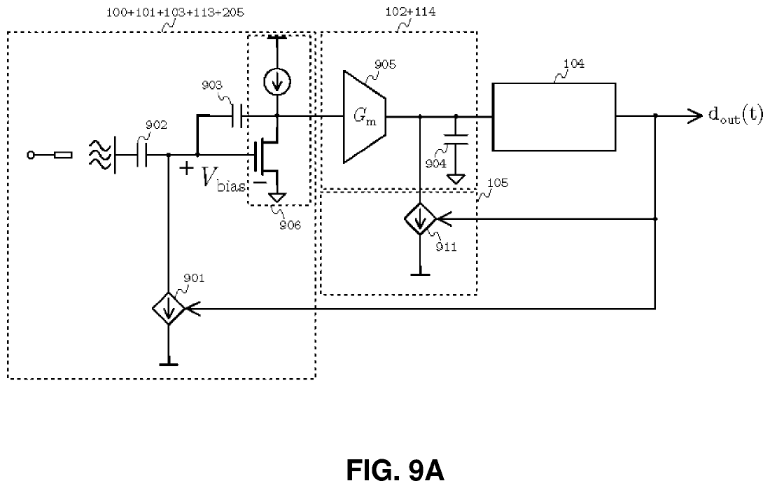

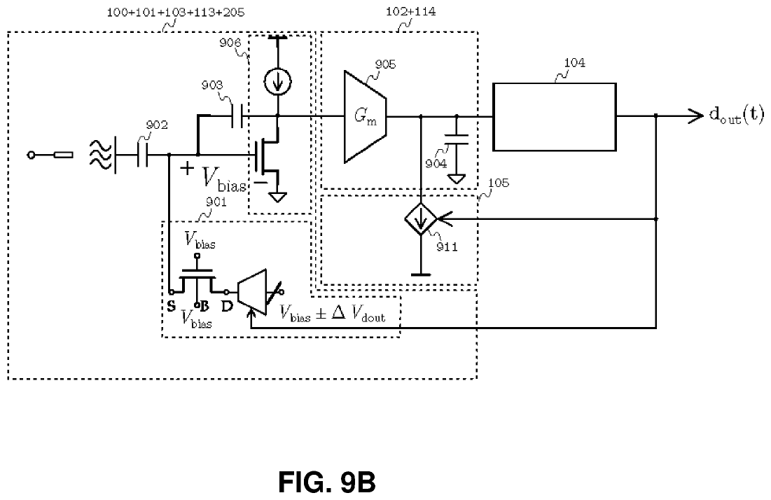

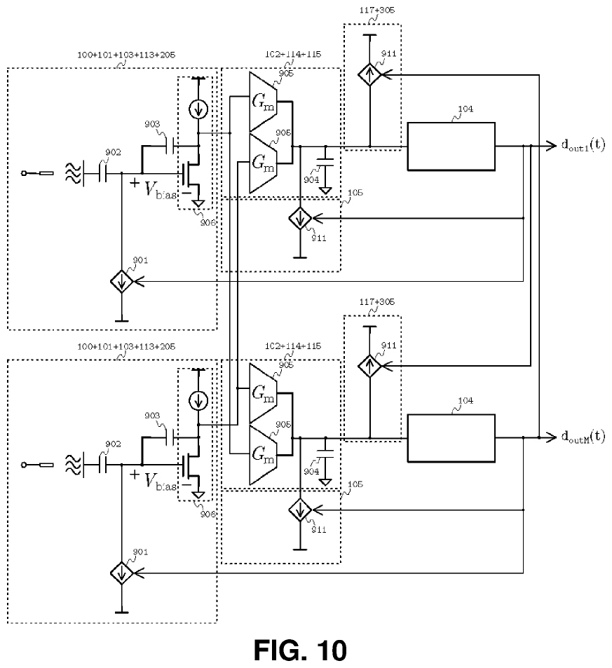

In an aspect of the invention, described in FIGS. 9A, 9B, and 10, the sensing stage (100) comprises a FET sensor, and the interfacing stage (101) performs capacitive amplification through the passivation capacitance of the FET sensor and a feedback capacitance, and wherein unfiltered intramodulator feedback signals, the low-pass-filtered intramodulator feedback signals, and the unfiltered intermodulator feedback signals are current signals subtracted in current-mode from the amplified input transduced signal (108) of the delta sigma modulators (3) that comprise the device.

In FIGS. 9A, 9B, and 10, the digital-to-analog conversion of the unfiltered intramodulator feedback path is performed using a current source (911) controlled by dₒᵤₜ(t). The digital-to-analog conversion of the low-pass intramodulator feedback path is performed using a current source and a metal-oxide-semiconductor (MOS) transistor (901) controlled by dₒᵤₜ(t). In FIG. 10, the digital-to-analog conversion of the unfiltered intermodulator feedback path is performed using a current source (911) controlled by dₒᵤₜ(t). The transduction, the capacitive amplification and the subtracting stages are performed by an amplifier (in this case a minimalistic implementation (906) comprising a current source and the metal-oxide-semiconductor (MOS) transistor of the FET sensor), the dielectric capacitance of the sensing membrane (902), and a feedback capacitor (903). The output voltage of the capacitive amplifier is connected to a transconductor (905) that converts it to a transconductor output current. After current-mode subtraction of the unfiltered intramodulator feedback signal and, optionally, the unfiltered intermodulator signal, the transconductor output current is integrated in the integrating capacitor (904) of a single-stage integrator. The integrating capacitor (904) is connected to the analog-to-digital encoder (104) that produces the digital output signal dₒᵤₜ(t).

To allow the configuration of very-low cut-off frequencies in a microchip, and to minimize the leakage at the gate of the MOS transistor, the controlled current source (901) of the low-pass-filtered intramodulator feedback path can be implemented as depicted in FIG. 9B: using an ultra-low leakage MOS transistor operating with a selectable drain-source voltage via an e.g. multiplexer stage. The transistor can be biased to have a null drain-source voltage when the output of dₒᵤₜ(t) is zero. It can also be biased to a null source-bulk voltages, which cause null conduction through the MOS transistor channel and the diffusion diodes, respectively, from the capacitive amplifier. While a non-zero dₒᵤₜ(t) selects a non-zero drain-source voltage, this voltage (i.e. ±ΔV_{dout}) can be set in practice to be also very low and proportional to dₒᵤₜ(t).

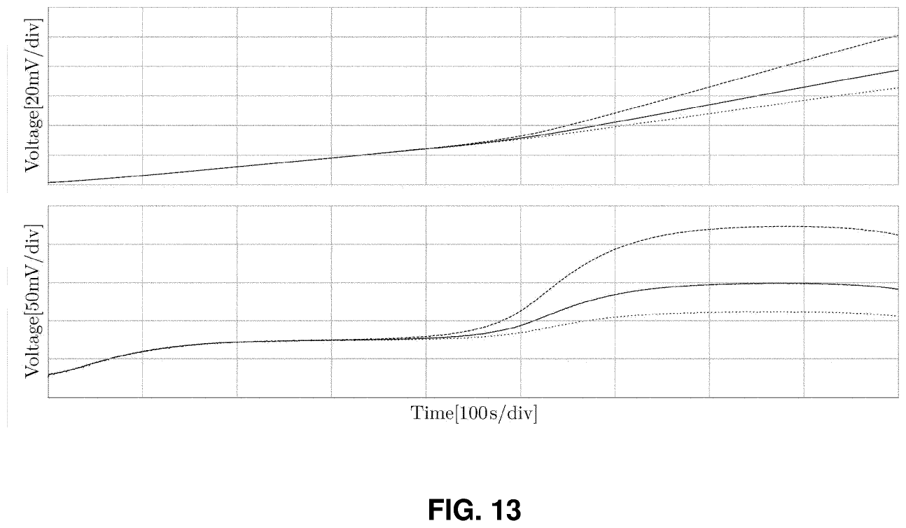

In FIG. 13, the solid line corresponds to an increase in the analyte concentration causing a similar effective Vₛₑₙₛ rate than the drift Vₛₑₙₛ rate; the dotted line corresponds to an increase in the analyte concentration causing an effective Vₛₑₙₛ rate of approximately half the drift Vₛₑₙₛ rate; the dashed line corresponds to an increase in the analyte concentration causing an effective Vₛₑₙₛ rate of approximately double the drift Vₛₑₙₛ rate. As seen in FIG. 13 (bottom), the device of FIGS. 9A and 9B can be configured to compress the increasing sum of drift and effective Vₛₑₙₛ signals into recovered bumps of amplitude proportional to the added rates by setting the cut-off frequency of the low-pass-filtered intramodulator feedback path at a value higher than that the drift for which attenuation is desired, and lower than the spectral components of interest of the effective Vₛₑₙₛ signal. This facilitates discrimination of the effective Vₛₑₙₛsignal to detect in front of the drift, and identification of the chemical reactive rising the concentration of the analyte of interest in e.g. ISFET-based detection of infectious diseases by measuring pH changes in interaction with DNA fragments or antigens. It also extends the dynamic range available over time in front of the sensor drift.

1.—A delta-sigma device characterized in that it comprises one or more transducers (2) and one or more delta-sigma modulators (3) wherein each of the transducers (2) comprises:
a sensing stage (100) intended to detect a property of the environment Xᵢₙ(t) (106) and configured to convert it into an electrical input signal (107), and
an interfacing stage (101), connected to the sensing stage (100), and configured to receive the electrical input signal (107), amplify the electrical input signal (107) and send amplified input transduced signals (108) to one or more of the delta-sigma modulators (3),
and wherein each of the delta-sigma modulators (3) comprises:
an input stage connected to the interfacing stages (101), comprising two subtracting stages (113, 114), and configured to receive an unfiltered intramodulator feedback signal (109) and a low-pass-filtered intramodulator feedback signal (110), and to subtract them from a sum of one or more of the amplified input transduced signals (108) to obtain a delta error signal (111),
a feedforward low-pass filtering stage (102), following the two subtracting stages (113, 114) of the input stage, configured to filter the delta error signal (111), generating a filtered delta error signal;
an analog-to-digital encoder (104), following the feedforward low-pass filtering stage (102), that converts the filtered delta error signal into a digital output signal dₒᵤₜ(t) (112),
an unfiltered intramodulator feedback path, that comprises one or more first digital-to-analog converters (105) between the analog-to-digital encoder (104) and a first of the two subtracting stages (114) of the input stage, that converts dₒᵤₜ(t) (112) into the unfiltered intramodulator feedback signal (109), and
a low-pass-filtered intramodulator feedback path that comprises a feedback low-pass filtering stage (103) and one or more second digital-to-analog converters (205), between the analog-to-digital encoder (104) and a second of the two subtracting stages (113) of the input stage, that converts dₒᵤₜ(t) (112) into the low-pass-filtered intramodulator feedback signal (110);
and wherein the cut-off frequency of the feedback low-pass filtering stage (103) is set between the range of background signal components and the range of signal of interest components.

2.—The device of claim 1, wherein the background signals are a drift and/or an offset.

3.—The device of claim 1, wherein each transducer (2) is connected to a single delta-sigma modulator (3) or to more than one delta-sigma modulator (3).

4.—The device of claim 1, wherein it comprises one or more transducers (2) and two or more delta-sigma modulators (3), and wherein the device additionally comprises a plurality of unfiltered intermodulator feedback paths that comprise one or more third digital-to-analog converters (305), connected to dₒᵤₜ(t) (112) of each delta-sigma modulator (3) and configured to convert dₒᵤₜ(t) into a plurality of unfiltered intermodulator feedback signals (116), and wherein the device comprises an additional subtracting stage (117) before the feedforward low-pass filtering stage (102) configured to receive the unfiltered intermodulator feedback signals (116) of each one of the other delta-sigma modulators (3) to subtract them from the delta error signal (111).

5.—The device of claim 1, wherein the feedforward low-pass filtering stage (102) or the feedback low-pass filtering stage (103) comprise one or more leaky or non-leaky integrator stages, each integrator stage being configured to integrate a respective input signal.

6.—The device of claim 5, wherein one or more of the leaky or non-leaky integrator stages of the feedforward low-pass filtering stage (102) is a small-signal circuit equivalent of the dynamic electrical response of the transducer (2) under small-signal excitation.

7.—The device of claim 1, wherein the analog-to-digital encoder (104) of the delta-sigma modulators (3) comprises a one-bit synchronous or asynchronous quantizer or a three-level asynchronous or synchronous quantizer.

8.—The device of claim 1, wherein the analog-to-digital encoder (104) of the delta-sigma modulators (3) comprises a one-bit asynchronous quantizer and a pulse generator that convert the filtered delta error signal into a digital pulsing signal dₒᵤₜ(t) (112).

9.—The device of claim 8, wherein the feedback low-pass filtering stage (103) additionally comprises a FIR (Finite Impulse Response) or IIR (Infinite Impulse Response) digital low-pass filter.

10.—The device of claim 9, wherein the feedback low-pass filtering stage (103) additionally comprises an asynchronous counter stage, with a predetermined clock period, connected between dₒᵤₜ(t) and the digital low-pass filter, and configured to integrate the number of asynchorous dₒᵤₜ(t) pulses throughout the clock period.

11.—The device of claim 1, wherein the analog-to-digital encoders (104) of the delta-sigma modulators (3) comprise a three-level asynchronous quantizer and a three-level bipolar pulse generator that convert the filtered delta error signal into a digital bipolar pulsing signal dₒᵤₜ(t) (112), wherein the three-level asynchronous quantizer is configured to send a signal to the three-level bipolar pulse generator to generate three different digital signals each one corresponding to a predetermined range of values of the filtered delta error signal received.

12.—The device of claim 4, wherein the sensing stage (100) and the interfacing stage (101) of the transducers (2) and a leaky integrator stage of the feedforward low-pass filtering stage (102) are three-electrode cells operating as a potentiostatic-amperometric sensor, and wherein the unfiltered intramodulator feedback signals (109) and the low-pass-filtered intramodulator feedback signals (110) are subtracted in current-mode from the amplified input signals, and the unfiltered intermodulator feedback signals (116) are subtracted in current-mode from the inputs of any of the integrator stages comprised in the feedforward low-pass filtering stage, wherein the feedforward low-pass filtering stage is connected to the analog-to-digital encoder (104), which is connected to the unfiltered intramodulator feedback path and the low-pass filtered intramodulator feedback path.

13.—The device of claim 12, further comprising a second current source (911) in the unfiltered intramodulator feedback path configured to perform digital-to-analog conversion controlled by dₒᵤₜ(t), and a first current source comprised of a metal-oxide-semiconductor (MOS) transistor (901) configured to perform amplification and digital-to-analog conversion of the low-pass intramodulator feedback path controlled by dₒᵤₜ(t).

14.—The device of claim 13, wherein the metal-oxide-semiconductor (MOS) transistor is operated with a selectable drain-source voltage biased to have a null drain-source voltage when the output of dₒᵤₜ(t) is zero or to a null source-bulk voltages, and, when the output of dₒᵤₜ(t) is not zero, a non-zero very low drain-source voltage is selected, being proportional to dₒᵤₜ(t).

15.—The device of claim 4, wherein the sensing stage (100) comprises a FET sensor, and the interfacing stage (101) performs capacitive amplification through the passivation capacitance of the FET sensor and a feedback capacitance, and wherein the low-pass-filtered intramodulator feedback signals (110), and the unfiltered intramodulator feedback signals (109), the unfiltered intermodulator feedback signals (116) are subtracted in current-mode from the amplified input transduced signals (108).
